(19) United States
(12) Patent Application Publication
(10) Pub. No.: US 2025/0372487 A1
(43) Pub. Date: Dec. 4, 2025

(54) INTERCONNECT ARRAY

(71) Applicant: TEXAS INSTRUMENTS INCORPORATED, DALLAS, TX (US)

(72) Inventors: NICOLE YABUUCHI, ANGELES (PH); LORRAINE DULDULAO QUIJANO, ANGELES (PH); VINCY ANN DANGANAN, PAMPANGA (PH)

(21) Appl. No.: 18/680,299

(22) Filed: May 31, 2024

(51) Int. Cl. H01L 23/495; H01L 21/48

(52) U.S. Cl. CPC H01L 23/49565; H01L 21/4842

(57) ABSTRACT

A substrate with an array of interconnects for IC (integrated circuit) includes die pads for receiving dies. The array of interconnects also includes leads arranged to circumscribe the die pads. A subset of the leads of that are proximal to a periphery of the substrate are opposed by dummy leads.

### TECHNICAL FIELD

This disclosure relates to an array of interconnects that can be singulated for IC (integrated circuit) packages.

### BACKGROUND

ICs (integrated circuits) packages are the cornerstone of modern electronics, found in everything from computers and mobile devices to automobiles and industrial machinery. As the demand for smaller, faster and more energy-efficient devices continues to grow, the semiconductor industry is challenged to improve IC packaging technologies to meet these demands.

Conventionally, IC packages have been constructed using an interconnect (alternatively referred to as a leadframe) as a support structure, providing mechanical stability, electrical connectivity and heat dissipation for a semiconductor die. The leadframe includes a die pad for mounting the semiconductor die.

Wettable flanks refer to a specific design feature of the leads in interconnects that are engineered to enhance solderability during an assembly process. The primary purpose of wettable flanks is to ensure robust mechanical and electrical connections by improving the lead's ability to attract and retain solder, thereby creating stronger, more reliable solder joints. This feature helps reduce manufacturing defects such as cold joints or insufficient solder coverage, leading to higher production yields and enhanced performance reliability in semiconductor devices.

### SUMMARY

A first example relates to a substrate with an array of interconnects for IC (integrated circuit) packages. The array of interconnects include die pads for receiving dies and leads arranged to circumscribe the die pads. As subset of the leads of that are proximal to a periphery of the substrate are opposed by dummy leads.

A second example relates to a method for forming an array of interconnects on a substrate. The method includes depositing a photoresist layer over a top surface of the substrate. The array of interconnects includes die pads, and each die pad is circumscribed by a corresponding set of leads. The method also includes patterning the photoresist layer to expose regions between leads of the set of leads for each die pad. The method includes etching the exposed regions between leads of the set of leads for each die pad to form cut lines in the array of interconnects. Each lead of the set of leads for each die pad opposes another lead. The method includes removing a remaining portion of the photoresist layer.

### BRIEF DESCRIPTION OF THE DRAWINGS

FIG. 1A illustrates an example of an array of interconnects.

FIG. 1B is a zoomed-in cross sectional view of a region of FIG. 1A that shows a lead opposing a dummy lead.

FIG. 2 illustrates an array of interconnects that is employable to implement the array of interconnects of FIG. 1A.

FIG. 3A illustrates a diagram of a portion of an array of interconnects.

FIG. 3B illustrates a zoomed-in region of FIG. 3A.

FIGS. 4A and 4B illustrates a multilayer view of an interconnect in an array of interconnects.

FIG. 5A illustrates a portion of a singulated interconnect where leads did not oppose leads.

FIG. 5B illustrates a zoomed-in cross-sectional view of the singulated interconnect of FIG. 5A.

FIG. 6A illustrates a portion of a singulated interconnect where leads opposed dummy leads.

FIG. 6B illustrates a zoomed-in cross-sectional view of the singulated interconnect of FIG. 6A.

FIGS. 7-19 illustrate stages of a method for fabricating an interconnect.

FIG. 20 illustrates a flowchart of an example method for forming an array of interconnects.

### DETAILED DESCRIPTION

This description relates to array of interconnects (e.g., lead frames) employed for semiconductor devices, such as IC (integrated circuit) packages, and a method for making the lead frames. In particular, the array of interconnects includes dummy leads along a periphery of the array of interconnects to address challenges related to solderability and mechanical stability when IC packages are mounted onto PCBs (printed circuit boards). By selectively positioning dummy leads to mirror functional leads where no adjacent functional leads exist, uniform etching depth across the array of interconnects is achieved, enhancing the overall solderability of wettable flanks on singulated interconnects of the array of interconnects.

The manufacturing process for these enhanced lead frames involves applying a photoresist pattern to a substrate to define areas for etching between functional leads and dummy leads, followed by a controlled etching process (e.g., half-etching) that does not penetrate completely through the substrate. This etching process is meticulously managed to ensure desired depth and uniformity, to ensure consistent solderability. The etching removes metallic material between the functional leads and the dummy leads to provide chamfers on the functional and dummy leads of the interconnects of the array of interconnects that have the same, or nearly the same height to improve singulation of the interconnects.

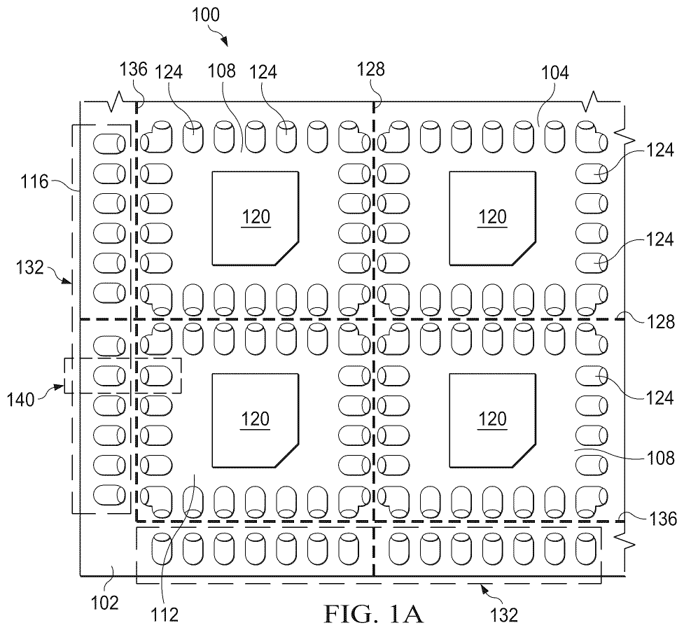

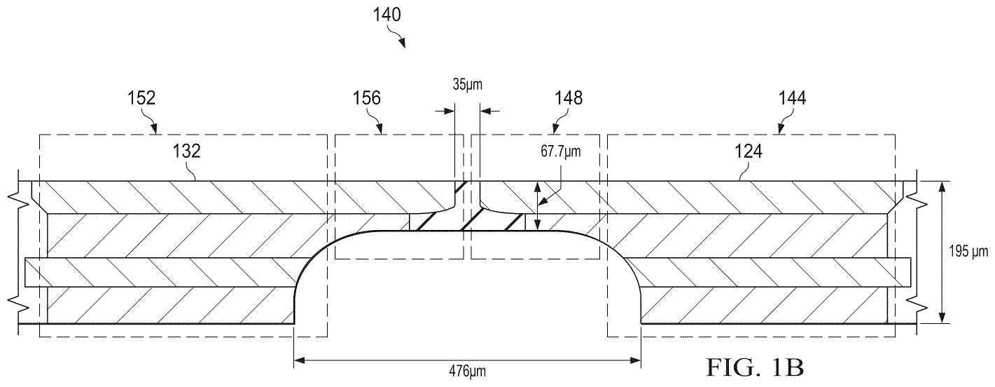

FIG. 1A illustrates an example of an array of interconnects 100. The array of interconnects 100 is formed on a substrate 102. In some examples, the substrate 102 is implemented as a sheet for the array of interconnects, such as a sheet of leadframes. There are at least four (4) interconnects in the array of interconnects 100. The array of interconnects 100 includes three types of interconnects, interior interconnects 104, edge interconnects 108 (two of which are shown) and corner interconnects 112. Each interconnect in the array of interconnects has a rectangular (e.g., square) shape. The interior interconnects 104 have opposing interconnects on each side (e.g., all four (4) sides). Edge interconnects 108 have opposing interconnects on three (3) sides, and one (1) side that is proximate a periphery 116 of the interconnects 100. The periphery 116 circumscribes the interconnects of the array of interconnects 100. Corner interconnects 112 are located at a corner of the array of interconnects 100, such that corner interconnects 112 have opposing interconnects on two (2) sides, and two (2) sides that are proximate to the periphery 116 of the array of interconnects 100.

Each interconnect, including the interior interconnects 104, the edge interconnects 108 and the corner interconnects 112 has a die pad 120 and leads 124 (only some of which are labeled). Stated differently, each interconnect includes a set of leads 124 (a subset of the leads 124) that circumscribe a respective die pad 120. In this manner, the leads 124 circumscribe the die pads 120. These leads 124 can alternatively be referred to as functional leads.

The leads 124 for the interior interconnects 104 oppose leads 124 of another interconnect. The gap (e.g., region) between the leads 124 of the adjacent interconnects provide a cutline 128 that facilitates singulation. The gap could be filled, for example, with a dielectric. Accordingly, a cutter (e.g., a plasma cutter, a diamond saw, etc.), can singulate the interior interconnects 104 by cutting along the cutlines 128. In some examples, such as situations where the interconnects of the array of interconnects 100 is implemented with routable lead frames, the leads 124 are conductively coupled with a corresponding die pad 120 though traces and/or vias in the substrate 102.

The leads 124 that are proximate to the periphery 116 of the array of interconnects 100 oppose dummy leads 132 (e.g., non-functional leads). For instance, a subset of the set of leads 124 of the edge interconnects 108 (e.g., one (1) side) that are proximate to the periphery 116 of the array of interconnects 100 oppose dummy leads 132. Similarly, a subset of the set of leads 124 of the corner interconnects 112 that are proximate to the periphery 116 (e.g., the two (2) sides that face the periphery 116) of the array of interconnects 100 also oppose dummy leads 132.

The dummy leads 132 are situated at the periphery 116 of the substrate 102. In some examples, the dummy leads 132 are not conductively coupled with a die pad 120 or the leads 124. Stated differently, the die pads 120 and the leads 124 are galvanically isolated from the dummy leads 132. The dummy leads 132 oppose leads 124 on the edge interconnects 108 and/or the corner interconnects 112. The dummy leads 132 are separated from an opposing lead 124 by a gap (e.g., region) filled with a dielectric material to form a cutline 136. The cutlines 136 can be cut with the same cutter employed to cut the cutlines 128. In fact, the gap between the dummy leads 132 and the leads 124 has the same (or nearly the same) properties, shape and thickness as the gap between the leads 124 that are opposing other leads 124 (e.g., such as the leads 124 of the interior interconnects 104). This gap enables wettable flanks (after singulation) on the leads 124 that are proximate to the periphery 116 (e.g., the leads 124 that are on opposite sides of a cutline 136) to have the same geometry and properties as wettable flanks formed on the leads 124 that oppose other leads (e.g., leads 124 on opposite sides of a cutline 128).

FIG. 1B is a zoomed-in cross section of a region 140 of FIG. 1A that shows a lead 124 opposing a dummy lead 132. FIGS. 1A and 1B employ the same reference numbers to denote the same structures. The lead 124 has a body portion 144 and a chamfer 148. Similarly, the dummy lead includes a body portion 152 and a chamfer 156. The body portion 144 of the lead 124 and the body portion 152 of the dummy lead 132 has a thickness of about 195 micrometers (μm). The chamfer 148 of the lead 124 and the chamfer 156 of the dummy lead 132 has a thickness of about 67.7 μm. Thus, the lead 124 and the dummy lead 132 have a thickness that varies from about 195 μm to about 67.7 μm.

The chamfer 148 of the lead 124 and the chamfer 156 (alternatively referred to as a chamfer portion) of the dummy lead 132 are separated by a distance of about 35 μm. This region can be filled with a dielectric material to reduce metal burs for singulation. The body portion 144 of the lead 124 and the body portion 152 of the dummy lead 132 are separated by a distance of about 476 μm. The distance between the body portion 144 of the lead 124 and the body portion 152 of the dummy lead 132 can define the distance between the lead 124 and the dummy lead 132. In other examples, this distance is about 300 um to about 500 μm.

Referring back to FIG. 1A, the geometry of a dummy lead 132 and corresponding lead 124 is the same (or nearly the same) as two (2) opposing leads 124. Thus, two (2) opposing leads 124 have chamfers that have thickness that is the same (or nearly the same) as the thickness of a chamfer of the dummy lead 132 and corresponding lead 124. Thus, by inclusion of the dummy leads 132, larger wettable flanks are provided on singulated interconnects of the array of interconnects 100. In fact, by implementing the array of interconnects 100 with the dummy leads 132, the geometry of the resultant wettable flanks formed on the leads 124 are the same (or nearly the same) independent of whether a particular interconnect (prior to singulation) was an interior interconnect 104, an edge interconnect 108 or a corner interconnect 112. In contrast, in conventional approaches where no such dummy leads are included, the resultant wettable flanks of leads that are proximal a periphery are smaller, which decreases reliability. Thus, including the dummy leads 132 improves yield of the interconnects singulated from the array of interconnects 100.

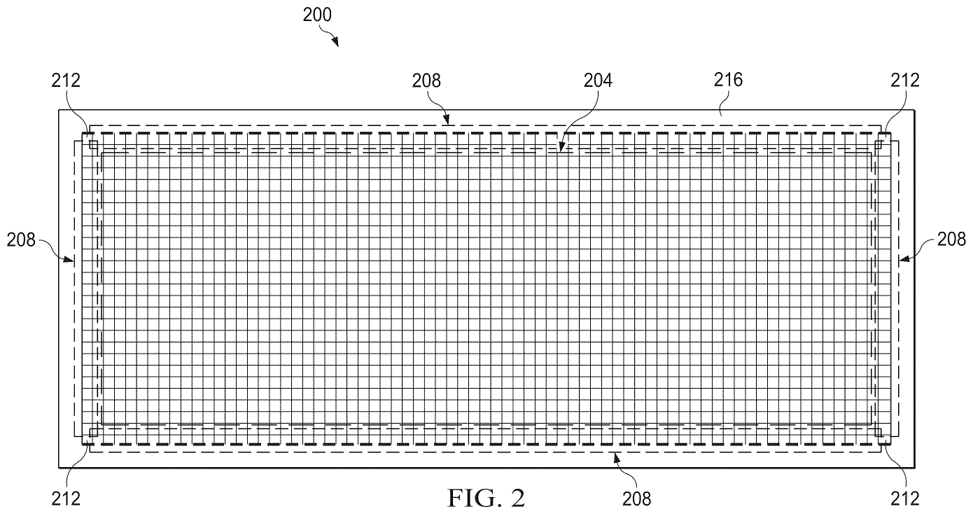

FIG. 2 illustrates an array of interconnects 200 that is employable to implement the array of interconnects 100 of FIG. 1A. The array of interconnects 200 has a rectangular shape. Similar to the array of interconnects 100 of FIG. 1A, the array of interconnects 200 includes interior interconnects 204, edge interconnects 208 and corner interconnects 212.

Cutlines formed at a periphery 216 of the array of interconnects 200 are positively impacted by the inclusion of dummy leads (e.g., the dummy leads 132 of FIGS. 1A and 1B). In particular, as explained with respect to FIG. 1A, inclusion of such dummy leads ensures that wettable flanks formed after singulation of the interconnects of the array of interconnects 200 have the same (or nearly the same) geometry (e.g., shape and thickness). In particular, the chamfer formed on the leads of the array of interconnects 100 have an equal, or nearly equal height.

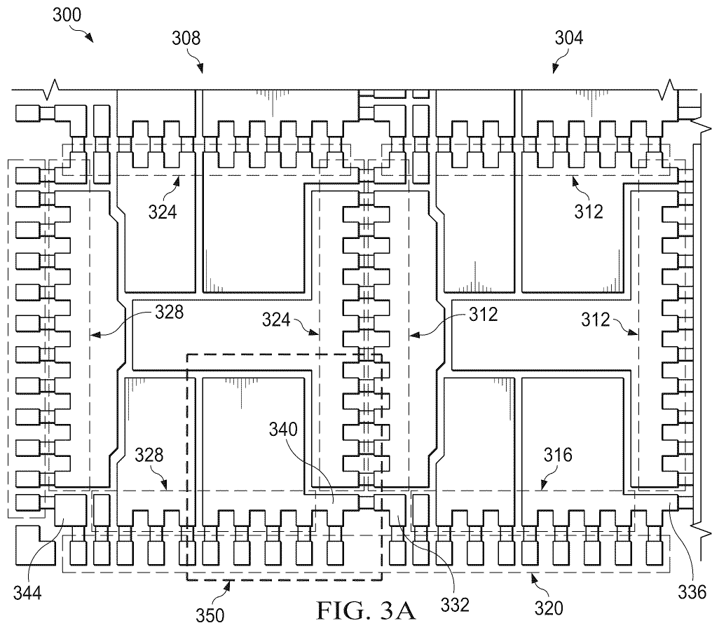

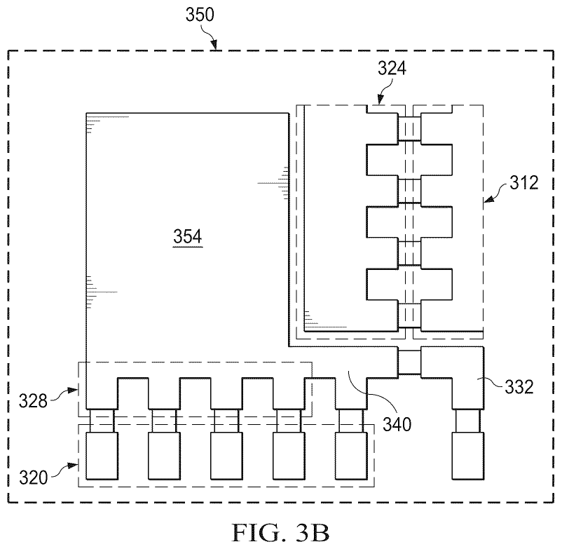

FIG. 3A illustrates a diagram of a portion of an array of interconnects 300, such as the array of interconnects 100 of FIG. 1A and/or the array of interconnects 200 of FIG. 2. The portion of the array of interconnects 300 includes an edge interconnect 304 and a corner interconnect 308. The edge interconnect 304 includes leads 312 opposing leads of another interconnect on three sides. Additionally, the edge interconnect 304 includes leads 316 opposing dummy leads 320 on one (1) side. Similarly, the corner interconnect 308 includes leads 324 opposing leads on another interconnect (including leads 312 of the edge interconnect 304). Additionally, the corner interconnect 308 includes leads 328 that oppose the dummy leads 320 on two (2) sides.

The leads 312 and 316 of the edge interconnect 304 and the leads 324 and the leads 328 of the corner interconnect 308 can be conductively coupled to plates on the edge interconnect 304 and the corner interconnect 308 respectively, such that the leads 312 and the leads 324 are functional leads. Conversely, the dummy leads 320 are arranged at a periphery of the array of interconnects 300 and are non-functional leads. Accordingly, the leads 328 of the corner interconnect 308, and the leads 316 of the edge interconnect 304 are galvanically isolated from the dummy leads 320.

Further, the edge interconnect 304 includes a first corner lead 332 and a second corner lead 336. The first corner lead 332 oppose a first corner lead 340 of the corner interconnect 308. The first corner lead 332 is located at a first corner of the edge interconnect 304 and the second corner lead 336 is located at a second corner of the edge interconnect 304. The first corner lead 332 of the edge interconnect 304 opposes both, a dummy lead 320 and a lead of the corner interconnect 308, namely a first corner lead 340 of the corner interconnect 308. Similarly, the second corner lead 336 opposes a lead of another interconnect and a dummy lead 320.

The corner interconnect 308 includes the first corner lead 340 and a second corner lead 344 located at respective first and second corners of the corner interconnect 308. The first corner lead 340 opposes both the first corner lead 332 of the edge interconnect 304 and a dummy lead 320. Additionally, the second corner lead 344 opposes two (2) dummy leads 320.

FIG. 3B illustrates a zoomed-in region 350 of FIG. 3A. FIGS. 3A and 3B employ the same reference numbers to denote the same structures. The region 350 illustrated in FIG. 3B includes a metallic plate 354 with a portion of the leads 324 that oppose dummy leads 320. In the example illustrated, this portion of the leads 324 extend from the metallic plate 354. The region 350 also includes the first corner lead 340 that oppose the first corner lead 332 of the edge interconnect 304 and a dummy lead 320. Further, the region 350 includes leads 324 of the corner interconnect 308 that oppose leads 312 of the edge interconnect 304.

Referring back to FIG. 3A, as demonstrated by the portion of the array of interconnects 300, inclusion of the dummy leads 320 enables each lead (functional lead) for the array of interconnects 300 to be opposed by another lead. As discussed with respect to FIG. 1A, this enables a larger wettable flank on a respective interconnect after singulation. In particular, compared with arrays of interconnects that do not include dummy leads, interconnects at a periphery of the array of interconnects (e.g., edge and corner interconnects) have smaller regions for cutlines, and more metal in such cutlines. However, including the dummy leads 320 increases the size of the gap between the leads 316 of the edge interconnect 304 and the dummy leads 320, and the gap between the leads 328 of the corner interconnect 308 and the dummy leads 320. Accordingly, the leads 316 of the edge interconnect 304 and the dummy leads 320, as well as the leads 328 of the corner interconnect 308 and the dummy leads 320 are spaced apart by about 270 μm or more (e.g., about 300 μm, in some examples). This increase in size reduces an amount of metal needed to be cut during singulation, reducing metal burrs and increasing the size of wettable flanks on the leads 316 of the edge interconnect 304 and on the leads 328 of the corner interconnect 308, which reduces failures of the edge interconnects 304 and the corner interconnects 308.

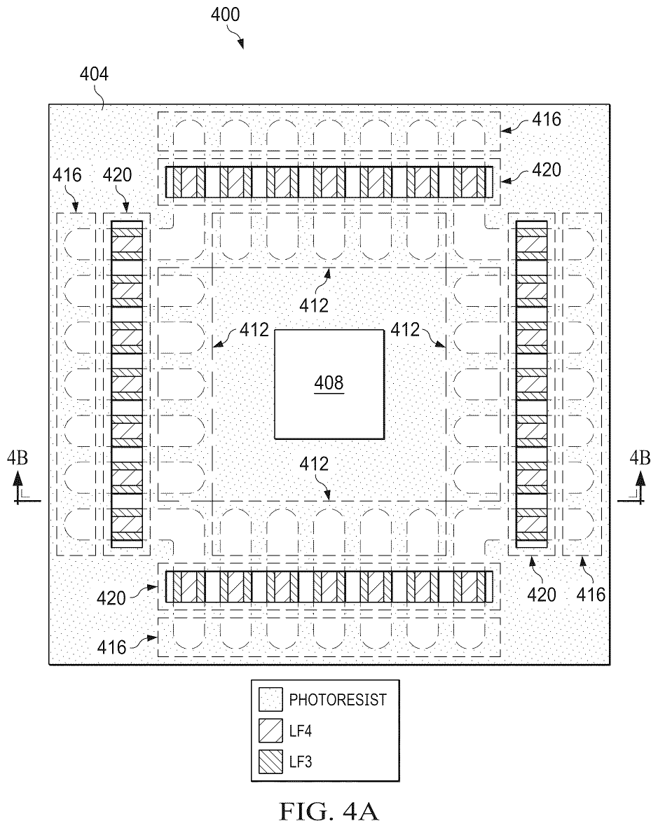

FIGS. 4A and 4B illustrates a multilayer view of an interconnect 400 (e.g., a leadframe) in an array of interconnects, such as the array of interconnects 100 of FIG. 1A. FIG. 4A illustrates an overhead view of the interconnect 400, and FIG. 4B illustrates a cross-sectional view of the interconnect 400 taken along line A-A of FIG. 4A. FIGS. 4A and 4B employ the same reference numbers to denote the same structures. FIG. 4B labels individual layers of the interconnect 400 as layer, LF1. . . . LF4.

In FIGS. 4A and 4B, a photoresist 404 (e.g., a dryfilm layer) overlays a top surface of the interconnect 400. The interconnect 400 includes a die pad 408 for receiving a die. The interconnect 400 also includes leads 412 that circumscribe the die pad 408. The leads 412 are functional leads that could be conductively coupled to the die pad 408 through internal traces of the interconnect 400, such as traces on layers LF1, LF2 and/or LF3 of the interconnect 400. FIG. 4A also illustrates opposing leads 416, namely leads that oppose the leads 412 of the interconnect 400. Some of the opposing leads 416 could be leads for other interconnects, and some of the opposing leads 416 could be dummy leads, such as in situations where the interconnect 400 is an edge interconnect (e.g., the edge interconnect 108 of FIG. 1A) or a corner interconnect (e.g., the corner interconnect 112 of FIG. 1A).

The opposing leads 416 and the leads 412 are separated by gaps 420. The gaps 420 can be about 270 to about 330 μm wide (e.g., about 300 μm in some examples). Stated differently, the gaps 420 cause the leads 412 and the lead 416 (some of which may be dummy leads) to be spaced part by about 300 μm or more. The gaps 420 include conductive material (e.g., metal, such as copper) at the L4 and L3 level. The photoresist 404 is patterned to expose the conductive material in the gaps 420. The conductive material is etched in a half-etching operation to remove the conductive material in the gaps 420, such that the leads 412 and the opposing leads 416 are not conductively coupled. Accordingly, the leads 412 and the opposing leads 416 are galvanically isolated from each other. Additionally, etching this conductive material provides for regions to form cutlines sufficiently large to ensure that the interconnect 400 can be singulated.

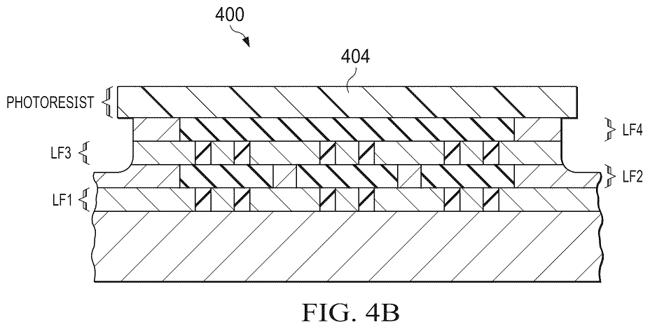

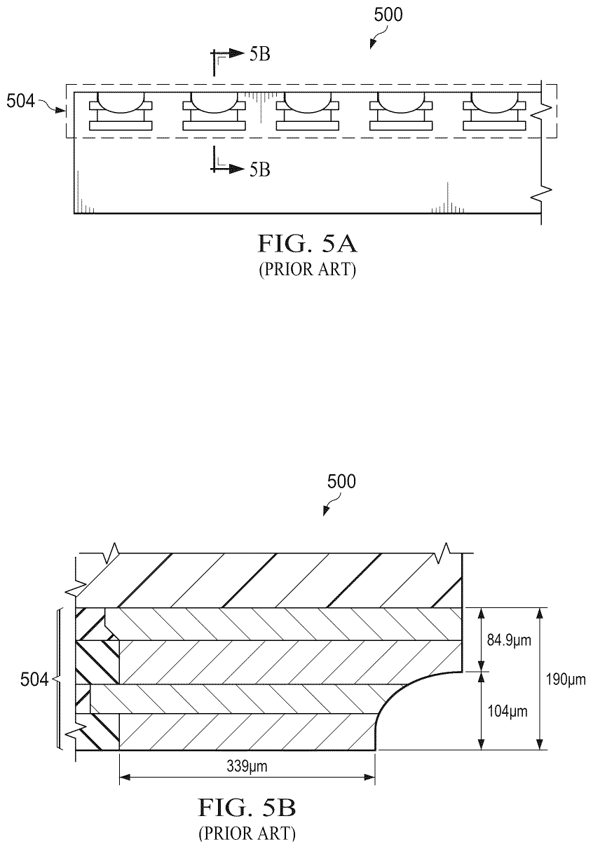

FIG. 5A illustrates a portion of a singulated interconnect 500 where leads 504 did not oppose leads. For example, the interconnect 500 was singulated from an array of interconnects that did not include dummy leads, and the leads 504 were proximal to a periphery of the array of interconnects. FIG. 5B illustrates a zoomed-in cross-sectional view of the singulated interconnect 500 taken along line A-A of FIG. 5A.

As illustrated in FIG. 5B, the lead 504 has a minimum thickness of about 84.9 μm, and a maximum thickness of about 190 μm. The lead 504 also has a chamfer height of about 104 μm that is measured from a bottom of the lead 504 to the minimum thickness. The relatively thick portion of the lead 504 with the minimum thickness of 84.9 μm can cause a metal bur on a wettable flank of the singulated interconnect 500.

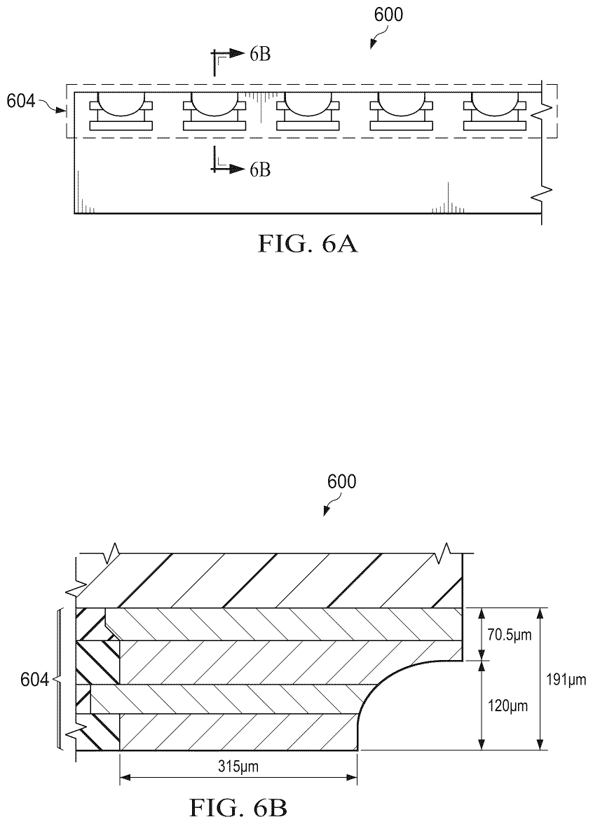

FIG. 6A illustrates a portion of a singulated interconnect 600 where leads 604 opposed dummy leads (e.g., the dummy leads 132 of FIG. 1A). For example, the interconnect 500 was singulated from an array of interconnects that included dummy leads, such as the array of interconnects 100 of FIG. 1A, and the leads 604 were proximal to a periphery of the array of interconnects. FIG. 6B illustrates a zoomed-in cross-sectional view of the singulated interconnect 600 taken along line A-A of FIG. 6A.

As illustrated in FIG. 5B, the lead 604 has a minimum thickness of about 70.5 μm, and a maximum thickness of about 191 μm. Accordingly, the lead 604 has a thickness that varies. In some examples, the thickness varies by different amounts, such as from about 65 μm to about 191 μm. The lead 604 also has a chamfer height of about 120 μm that is measured from a bottom of the lead 604 to the minimum thickness. The relatively thin portion of the lead 604 with the minimum thickness of 70.5 μm can increase the size of the wettable flank of the singulated interconnect 500, and reduce the chances of a metal burr during singulation. By including the dummy leads, each lead of an array of interconnects (including edge and corner interconnects) has chamfers with equal or nearly equal height.

As compared to the lead 504 of FIGS. 5A and 5B, the leads 604 of FIGS. 6A and 6B have a larger variance in size, resulting in large chamfer height on the leads 604 of FIGS. 6A and 6B. This larger chamfer height reduces the amount of metal cut during singulation of the singulated interconnect 600 of FIGS. 6A and 6B relative to the singulated interconnect 500 5A and 5B, which in turn increase a size of the resultant wettable flank.

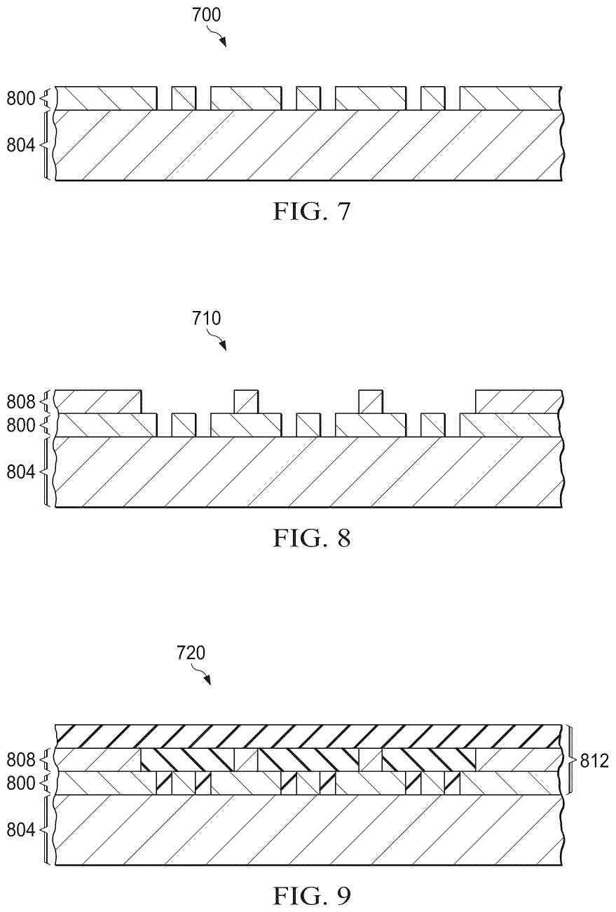

FIGS. 7-19 illustrate stages of a method for fabricating an interconnect, such as the interconnect 400 of FIGS. 4A and 4B or one of the interconnects of the array of interconnects 100 of FIG. 1A. The method of FIGS. 7-19 illustrates how gaps between leads that oppose each other are formed, particularly, in situations where leads of the interconnect oppose dummy leads.

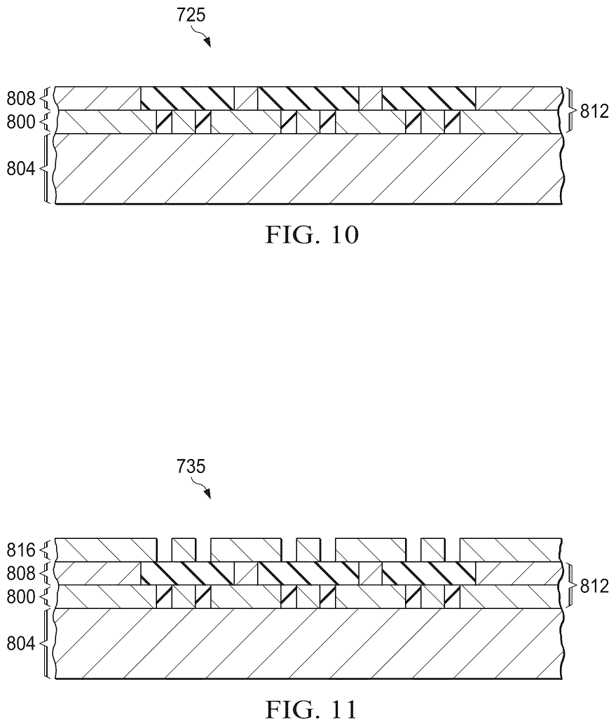

As illustrated in FIG. 7, at 700, in a first stage, a first metal layer pattern 800 is plated on a metal carrier 804. As illustrated in FIG. 8, in a second stage, at 710, a second metal layer pattern 808 (e.g., copper or other metal) is plated on the first metal layer pattern 800. As illustrated in FIG. 9, in a third stage at 720, a first dielectric layer 812 is applied to the second metal layer pattern 808 and to the first metal layer pattern 800. As illustrated in FIG. 10, in a fourth stage, at 725, a portion of the first dielectric layer 812 is removed in a grinding operation, such that regions of the second metal layer pattern 808 are exposed.

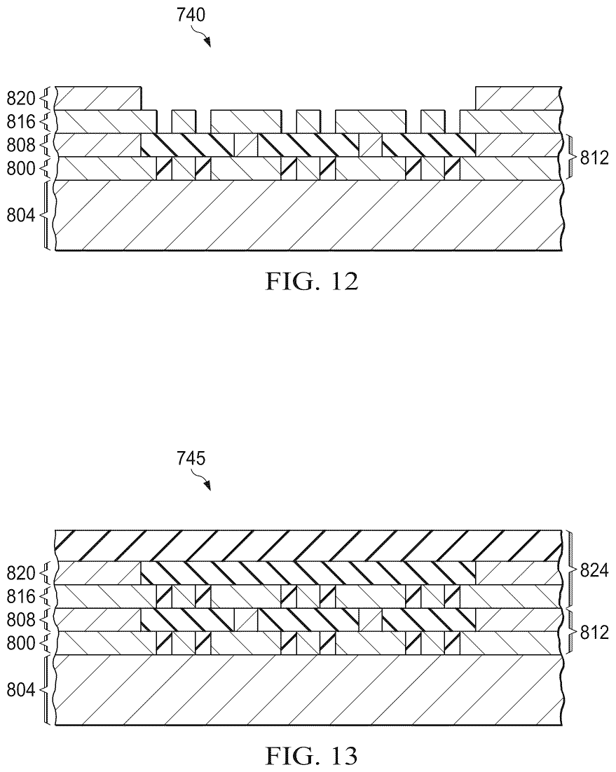

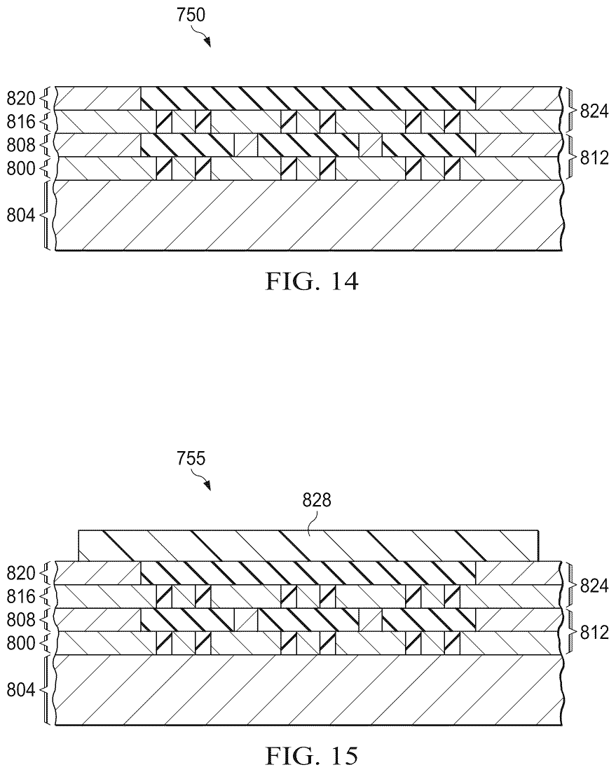

As illustrated in FIG. 11, in a fifth stage, at 735, a third metal layer pattern 816 is plated on the first dielectric layer 812 and on the second metal layer pattern 808. As illustrated in FIG. 12, in a sixth stage, at 740 a fourth metal layer pattern 820 is deposited on the third metal layer pattern 816. As illustrated in FIG. 13, in a seventh stage at 745, a second dielectric layer 824 is deposited on the first dielectric layer 812, the third metal layer pattern 816 and the fourth metal layer pattern 820. As illustrated in FIG. 14, in an eighth stage, at 750, a portion of the second dielectric layer 824 is removed in a grinding operation, such that regions of the third metal layer pattern 816, the fourth metal layer pattern 820 and the second dielectric layer 824 are exposed.

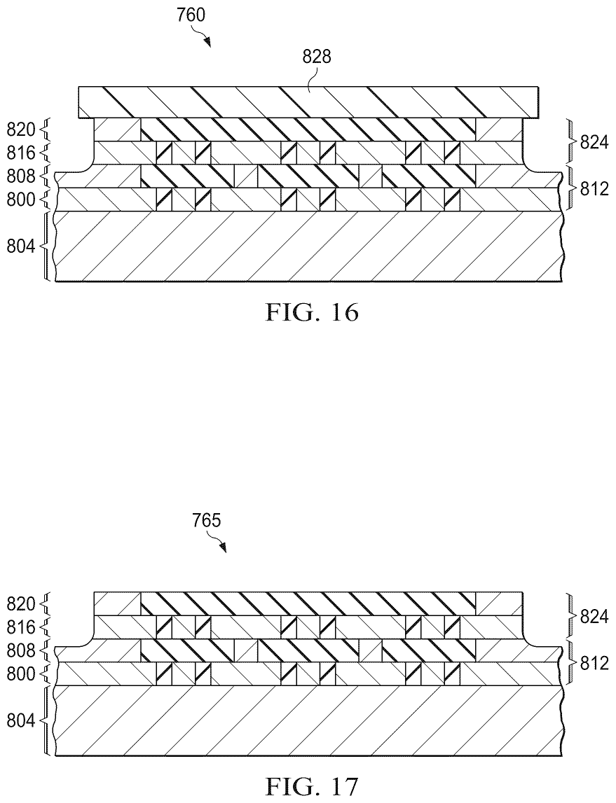

As illustrated in FIG. 15, in a ninth stage, at 755, a photoresist layer 828 (e.g., a layer of dryfilm) is overlaid on the second dielectric layer 824 and the fourth metal layer pattern 820. Also, at 755 the photoresist layer 828 is patterned to expose gaps between opposing leads (e.g., the gaps 420 of FIG. 4A). As illustrated in FIG. 16, in a tenth stage at 760 portions of the fourth metal layer pattern 820, the third metal layer pattern 816, the second metal layer pattern 808 and the first metal layer pattern 800 are etched (e.g., in a half-etching operation) to form chamfers at edges of the resultant interconnect. Thus, at the completion of the tenth stage at 760, the resultant interconnect has the same structure as the interconnect 400 of FIG. 4B.

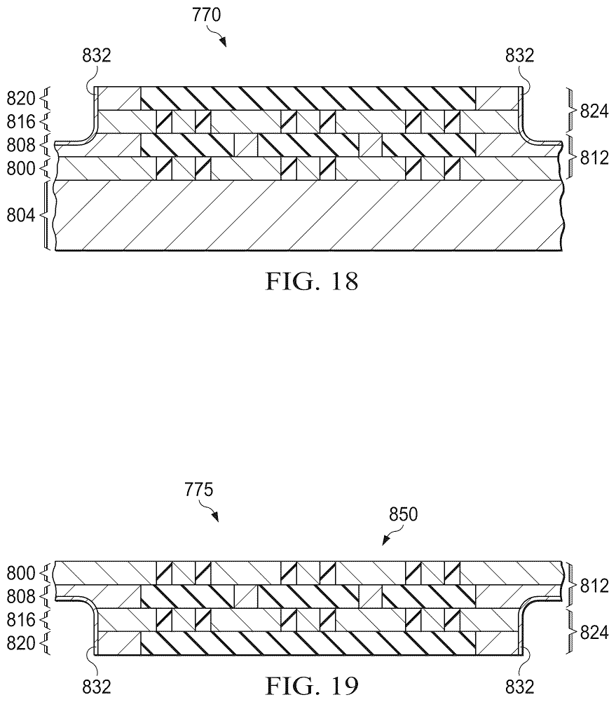

As illustrated in FIG. 17, in an eleventh stage at 765, the photoresist layer 828 is stripped. As illustrated in FIG. 18, in a twelfth stage at 770, a plated palladium finish (PPF) 832, or other similar material is deposited on the etched areas, such that the PPH (or other metal) is deposited on a cutline (e.g., between the interconnect and a periphery of an array of interconnects or between another interconnect of the array of interconnects). As illustrated in FIG. 19, in a thirteenth stage at 775, the metal carrier 804 is removed in a de-carrier operation to provide an interconnect 850 (e.g., a routable leadframe). The de-carrier operation executed at 870 exposes a region of the first metal layer pattern 800 to enable the second metal layer pattern 808 (connection pads) to be conductively coupled to leads formed on the first metal layer pattern 800.

As illustrated in FIGS. 8-19, by implementing the method, chamfers at the periphery of the interconnect are formed in operations at 755, 760, 765 and 770. Thus, the benefits of the chamfers (reduced metal for cutting) is achieved with adding relatively few processing operations to form the interconnect 850.

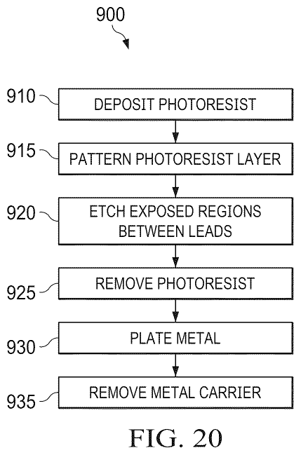

FIG. 20 illustrates a flowchart of an example method 900 forming an array of interconnects (e.g., the array of interconnects 100 of FIG. 1A) on a substrate (e.g., the substrate 102 of FIG. 1A). At block 910, a photoresist layer is deposited over a top surface of the substrate. The array of interconnects includes die pads, and each die pad is circumscribed by a corresponding set of leads. The substrate includes dummy leads proximal to a periphery of the array of interconnects, and each dummy lead opposes a lead of the set of leads for a corresponding die pad proximal to the periphery of the array of interconnects.

At block 915, the photoresist layer is patterned to expose regions between leads of the set of leads for each die pad and regions between leads and the dummy leads. In some examples, these regions are at least 300 μm. At block 920, the exposed regions between leads of the set of leads for each die pad are etched to form cutlines in the array of interconnects. Accordingly, in the array of interconnects each lead of the set of leads for each die pad opposes another lead. Some of the leads in the array of interconnects are dummy leads (e.g., non-functional leads), and some of the leads are functional leads conductively coupled with a respective die pad. At block 925, a remaining portion of the photoresist layer is removed in a stripping operation.

At block 930, the region forming the cutlines is plated with metal (e.g., a PPF). At block 935, a metal carrier of the substrate is removed to form the array of interconnects.

In this description, unless otherwise stated, “about,” preceding a parameter means being within +/−10 percent of that parameter. Modifications are possible in the described embodiments, and other embodiments are possible, within the scope of the claims.

What is claimed is:

1. A substrate with an array of interconnects for IC (integrated circuit) packages comprising:
die pads for receiving dies; and
leads arranged to circumscribe the die pads, wherein a subset of the leads of that are proximal to a periphery of the substrate are opposed by dummy leads.

2. The substrate of claim 1, wherein the dummy leads are configured to be removed during singulation of interconnects in the array of interconnects.

3. The substrate of claim 1, wherein the leads in the subset of the leads are galvanically isolated from the dummy leads.

4. The substrate of claim 3, wherein the leads in the subset of the leads are spaced apart from the dummy leads by about 300 micrometers or more.

5. The substrate of claim 3, wherein a portion of the leads extend from a metallic plate.

6. The substrate of claim 1, wherein leads of the subset of the leads have a thickness that varies from about 65 micrometers to about 191 micrometers.

7. The substrate of claim 1, wherein each of the leads has a chamfer with a nearly equal height.

8. The substrate of claim 1, wherein the leads are wettable flanks.

9. A method for forming an array of interconnects on a substrate, the method comprising:
depositing a photoresist layer over a top surface of the substrate, wherein the array of interconnects includes die pads, and each die pad is circumscribed by a corresponding set of leads;
patterning the photoresist layer to expose regions between leads of the set of leads for each die pad;
etching the exposed regions between leads of the set of leads for each die pad to form cut lines in the array of interconnects, wherein each lead of the set of leads for each die pad opposes another lead; and
removing a remaining portion of the photoresist layer.

10. The method of claim 9, wherein the substrate includes dummy leads proximal to a periphery of the array of interconnects, and each dummy lead opposes a lead of the set of leads for a corresponding die pad proximal to the periphery of the array of interconnects.

11. The method of claim 10, further comprising singulating the interconnects of the array of interconnects, wherein the singulating includes removing the dummy leads.

12. The method of claim 10, wherein the regions between the leads are at least 300 micrometers wide.

13. The method of claim 10, wherein the leads in the set of leads opposing the dummy leads are spaced apart from the dummy leads by about 300 micrometers or more.

14. The method of claim 10, wherein a portion of the leads of the set of leads extend from a metallic plate.

15. The method of claim 10, wherein each of the leads have a thickness that varies from about 65 micrometers to about 190 micrometers.

16. The method of claim 10 wherein each of the leads has a chamfer with a nearly equal thickness.

17. The method of claim 10, wherein the leads of the set of leads for each die pad are wettable flanks.

18. The method of claim 10, wherein the exposed regions are filled with a dielectric.

19. The method of claim 10, further comprising plating a metal in the cut lines.

20. The method of claim 19, further comprising removing a metal carrier from a bottom surface of the substrate in a de-carrier operation.
